(19) United States
(12) Patent Application Publication
(10) Pub. No.: US 2026/0026104 A1
(43) Pub. Date: Jan. 22, 2026

(54) DISPLAY DEVICE

(71) Applicant: Sharp Display Technology Corporation, Kameyama City (JP)

(72) Inventors: Hiromi ENOMOTO, Kameyama City (JP); Kazuya SHIO, Kameyama City (JP); Yoshimizu MORIYA, Kameyama City (JP)

(21) Appl. No.: 19/272,995

(22) Filed: Jul. 17, 2025

(30) Foreign Application Priority Data
Jul. 19, 2024 (JP) 2024-115523

(51) Int. Cl. H10D 86/40; G02F 1/1362; G02F 1/1368; H10D 86/60

(52) U.S. Cl. CPC H10D 86/441; G02F 1/136286; G02F 1/1368; H10D 86/60

(57) ABSTRACT

A display device includes a first substrate having a main surface having a display area in which an image is to be displayed and a non-display area in which the image is not to be displayed, at least one first wiring line disposed in the display area of the first substrate and extending in a first direction, a signal supply unit disposed in a first end portion in the non-display area of the first substrate in the first direction, and connected at least to the at least one first wiring line, the signal supply unit being configured to supply a signal to the at least one first wiring line, a common electrode disposed in the display area of the first substrate, and at least one common wiring line disposed in the non-display area of the first substrate and connected to the common electrode.

### CROSS REFERENCE TO RELATED APPLICATION

The present application claims priority from Japanese Application JP2024-115523, filed on Jul. 19, 2024, the content of which is hereby incorporated by reference into this application.

### BACKGROUND

### 1. Field

The technology disclosed in this specification relates to a display device that suppresses the occurrence of crosstalk.

### 2. Description of the Related Art

As examples of display devices, display devices described in Japanese Unexamined Patent Application Publication No. 2013-182127 and Japanese Unexamined Patent Application Publication No. 9-274470 are known. The display device described in Japanese Unexamined Patent Application Publication No. 2013-182127 is a liquid crystal display that includes an array substrate and a plurality of pixels that are arranged in a row direction and a column direction. Each pixel includes one or more pixel components that are driven independently, and a pitch of the pixel components in the row direction is substantially the same as or greater than a pitch of the pixel components in the column direction. The array substrate includes gate bus lines, a first insulating film provided on the gate bus lines, source bus lines and common bus lines provided on the first insulating film, a second insulating film provided on the source bus lines and the common bus lines, and a transparent common electrode provided on the second insulating film. The gate bus lines extend in the row direction, the source bus lines and the common bus lines extend in the column direction, and the common electrode is connected to the common bus lines through a contact hole formed in the second insulating film in a display area.

In the drive method in the display device described in Japanese Unexamined Patent Application Publication No. 9-274470, when opposite electrodes are driven with polarity inversion in synchronization with the polarity inversion of row electrodes, the row electrodes are electrically floated immediately after the polarity inversion.

In the display device described in Japanese Unexamined Patent Application Publication No. 2013-182127, the common bus lines are provided adjacent to the source bus lines in the display area, and the common bus lines are connected to the common electrode on the gate bus lines through the contact hole. However, depending on the display devices, in some cases, it is difficult to provide the common bus lines in the display area. In such a case, it may be difficult to reduce the occurrence of crosstalk.

In the display device described in Japanese Unexamined Patent Application Publication No. 9-274470, a switch group is provided to control the row electrodes such that the row electrodes are electrically floated immediately after the polarity inversion is performed, and the operation of the switch group is controlled. However, depending on the display devices, in some cases, it is difficult to provide such a switch group, and in such a case, it may be difficult to reduce the occurrence of crosstalk.

The technology described in this specification has been made under the above-described circumstances, and made to suppress the occurrence of crosstalk by using a method different from known methods.

### SUMMARY

A display device according to the technology described in this specification includes a first substrate having a main surface having a display area in which an image is to be displayed and a non-display area in which the image is not to be displayed, at least one first wiring line disposed in the display area of the first substrate and extending in a first direction, a signal supply unit disposed in a first end portion in the non-display area of the first substrate in the first direction and connected at least to the at least one first wiring line to supply a signal to the at least one first wiring line, a common electrode disposed in the display area of the first substrate, and at least one common wiring line disposed in the non-display area of the first substrate and connected to the common electrode. The signal supply unit includes two first signal supply units disposed on the main surface in the first end portion and on both end sides in a second direction intersecting the first direction, and at least two second signal supply units disposed between the two first signal supply units in the second direction in the first end portion and spaced apart in the second direction, the at least one common wiring line includes at least two common wiring lines disposed at positions on end sides of the two first signal supply units in the second direction respectively, and the at least two common wiring lines are connected to the two first signal supply units respectively, the first signal supply units are configured to supply a common potential signal to the common wiring lines, and each of the first signal supply units is disposed such that a first interval between the first signal supply unit and the adjacent second signal supply unit in the second direction is wider than a second interval between the two second signal supply units adjacent to each other in the second direction.

### BRIEF DESCRIPTION OF THE DRAWINGS

FIG. 1 is a plan view of a liquid crystal panel, a driver, a flexible substrate, and other elements in a liquid crystal display device according to a first embodiment;

FIG. 2 is a cross-sectional view of the liquid crystal panel, the driver, the flexible substrate, and other elements according to the first embodiment;

FIG. 3 is a circuit diagram of an electrical structure of an array substrate in the liquid crystal panel according to the first embodiment;

FIG. 4 is a plan view of source wiring, common wiring, a driver, a sealing section, and other elements in the liquid crystal panel according to the first embodiment;

FIG. 5 is a cross-sectional view of the liquid crystal panel according to the first embodiment taken along line V-V in FIG. 4;

FIG. 6A is a graph showing the change in potential of a common electrode in reference example 1 of reference experiment 1 according to the first embodiment;

FIG. 6B is a graph showing the change in potential of a common electrode in reference example 2 of reference experiment 1 according to the first embodiment;

FIG. 7 is a graph showing the change in crosstalk ratio in reference experiment 1 according to the first embodiment;

FIG. 8 is a graph showing the results of reference example 1 of reference experiment 2 according to the first embodiment;

FIG. 9 is a graph showing the results of reference example 2 of reference experiment 2 according to the first embodiment;

FIG. 10 is a plan view of source wiring, common wiring, a driver, a sealing section, and other elements in a liquid crystal panel according to a second embodiment;

FIG. 11 is a plan view of source wiring, common wiring, a driver, a sealing section, and other elements in a liquid crystal panel according to a third embodiment; and

FIG. 12 is a plan view of a liquid crystal panel, a driver, a flexible substrate, and other elements in a liquid crystal panel according to a fourth embodiment.

### DESCRIPTION OF THE EMBODIMENTS

### First Embodiment

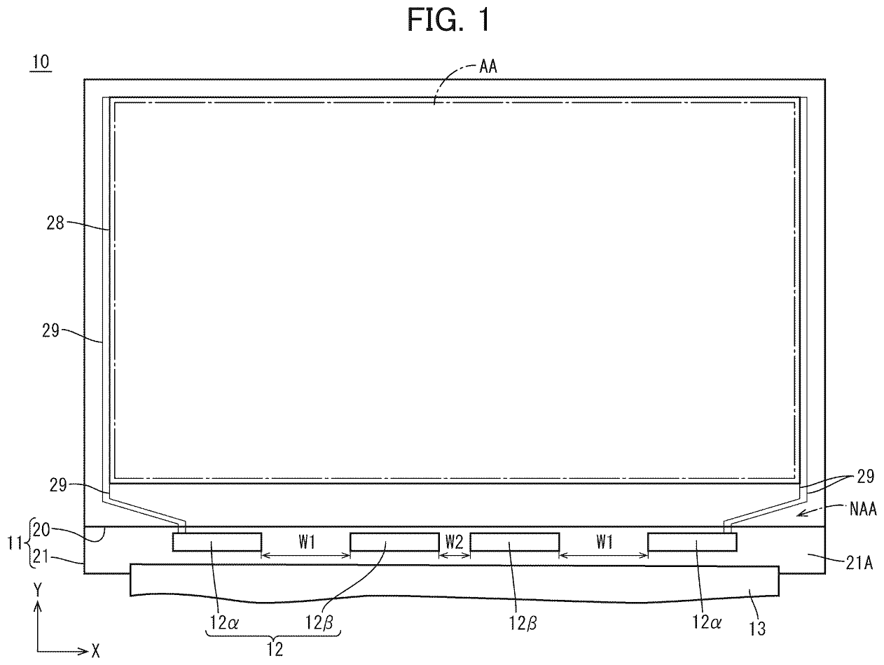

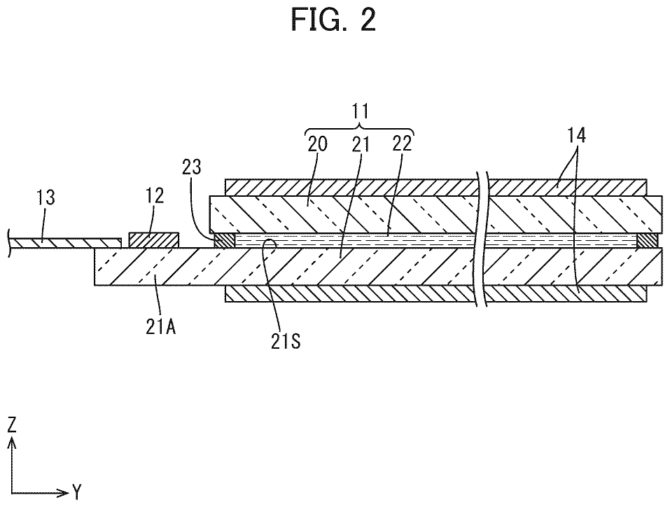

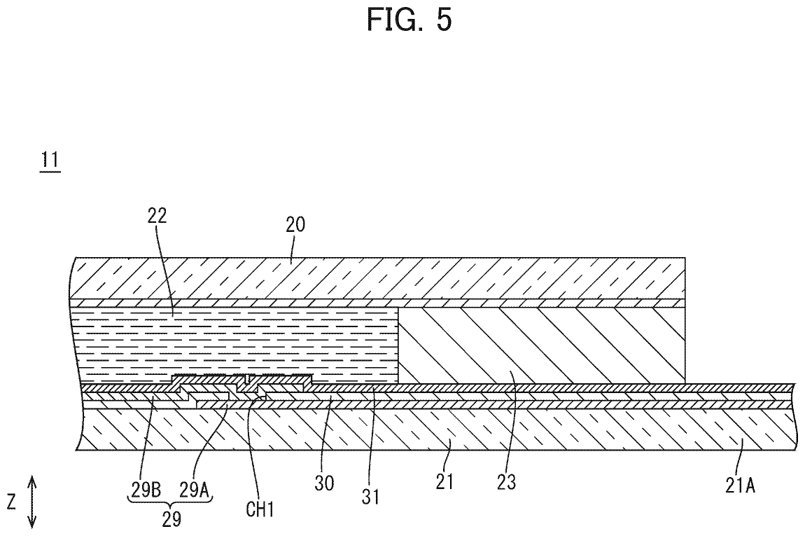

The first embodiment will be described with reference to FIG. 1 to FIG. 9. In this embodiment, a liquid crystal display device 10 will be described as an example. The X-axis, Y-axis, and Z-axis are shown on some of the drawings, and each axis direction corresponds to the direction indicated in each drawing. In FIG. 2 and FIG. 5, the upper side denotes the front side and the lower side denotes the rear side.

The liquid crystal display device 10 includes, as illustrated in FIG. 1, at least a liquid crystal panel (display device, display panel) 11 that has a horizontally elongated rectangular shape and is configured to display images, and a backlight device (illumination device) that emits light to be used for display to the liquid crystal panel 11. The backlight device is disposed on the rear side (back side) with respect to the liquid crystal panel 11, and includes a light source (e.g., an LED) that emits white light and an optical component and other components that apply optical effects to the light from the light source to convert the light into planar light. In the liquid crystal panel 11, a display area AA is a central portion of a main surface 21S of an array substrate 21, which will be described below, and images are displayed in the display area AA. In the liquid crystal panel 11, a non-display area NAA is a frame-shaped outer peripheral portion surrounding the display area AA in the main surface 21S, and images are not displayed in the non-display area NAA.

The liquid crystal panel 11 will be described with reference to FIG. 2 in addition to FIG. 1. The liquid crystal panel 11 includes a pair of substrates 20 and 21 that are sealed as illustrated in FIG. 1 and FIG. 2. Of the pair of substrates 20 and 21, the front side is an opposite substrate (second substrate) 20, and the rear side is the array substrate (first substrate) 21. Each of the opposite substrate 20 and the array substrate 21 is formed by laminating various films on an inner surface side of a glass substrate. On the inner surface side of the array substrate 21, a common electrode 28 that is provided at least across the entire display area AA, and a common wiring line 29 that is connected to the common electrode 28 are provided. The common electrode 28 and the common wiring line 29 will be described in detail below. Between the pair of substrates 20 and 21, a liquid crystal layer 22 that contains liquid crystal molecules, which are substances whose optical properties change in response to the application of an electric field, is provided. Between the pair of substrates 20 and 21, a sealing member 23 that seals the liquid crystal layer 22 is provided. On the outer surface side of each of the substrates 20 and 21, a polarizing plate 14 is bonded.

The opposite substrate 20 has a short side dimension that is shorter than a short side dimension of the array substrate 21, as illustrated in FIG. 1 and FIG. 2. The opposite substrate 20 is sealed such that one end portion in the short side direction (Y-axis direction) is aligned with respect to the array substrate 21. Accordingly, the other end portion of the array substrate 21 in the short side direction (first direction) protrudes laterally with respect to the opposite substrate 20 and is exposed, and the other end portion is referred to as a first end portion 21A. The entire of the first end portion 21A is the non-display area NAA, and on which a driver (signal supply unit) 12 and a flexible substrate 13 for supplying various signals are mounted. The sealing member 23 extends along an outer peripheral end portion of the opposite substrate 20 and has a rectangular frame shape to surround the liquid crystal layer 22.

The driver 12 comprises an LSI chip that includes an internal drive circuit. The driver 12 is mounted on the first end portion 21A of the array substrate 21 by Chip On Glass (COG) mounting. The driver 12 processes various signals that are transmitted by the flexible substrate 13. The driver 12 is disposed to be adjacent to the display area AA on one side in the Y-axis direction as illustrated in FIG. 1 and FIG. 2, and is disposed between the flexible substrate 13, which will be described below, and the display area AA. The driver 12 has a horizontally elongated rectangular shape in plan view. The driver 12 comprises four drivers that are disposed in line in the X-axis direction with a space therebetween in the X-axis direction in the first end portion 21A. The driver 12 is capable of supplying various signals to a source wiring line 27 or the like that is provided on the array substrate 21. The driver 12 is connected to at least the source wiring line 27 to supply image signals (signals) to the source wiring line 27. The flexible substrate 13 has a structure in which a plurality of wiring patterns is formed on a base material comprising a synthetic resin material (e.g., a polyimide resin) having insulating properties and flexibility. The flexible substrate 13 is connected at one end to the first end portion 21A of the array substrate 21 and at the other end to an external circuit board (e.g., a control board).

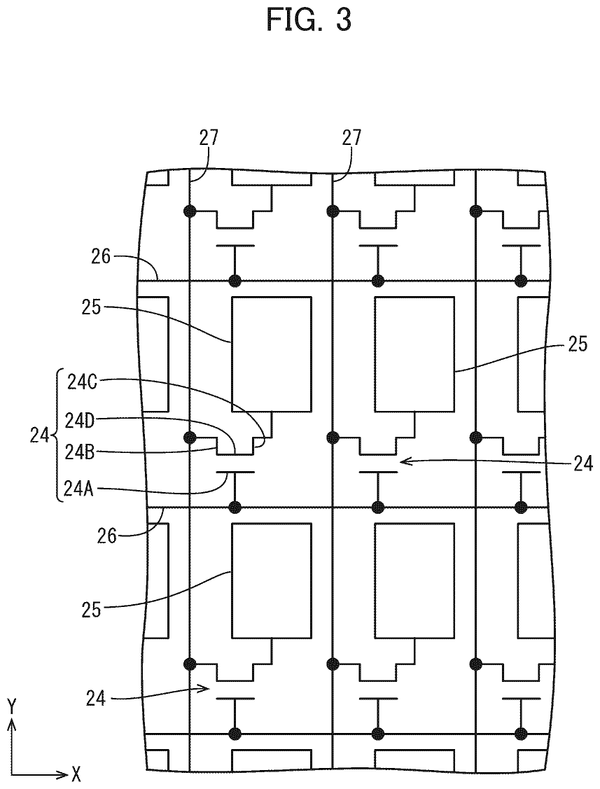

Next, the structure of the display area AA in the array substrate 21 is described with reference to FIG. 3. On the inner surface side of the array substrate 21 in the display area AA, as illustrated in FIG. 3, at least TFTs (transistors, switching elements) 24 and pixel electrodes 25 are provided. The plurality of TFTs 24 and the pixel electrodes 25 are spaced apart in the X-axis direction and in the Y-axis direction in a matrix (rows and columns) pattern. Around these TFTs 24 and pixel electrodes 25, gate wiring lines (second lines, scanning lines) 26 and source wiring lines (first lines, image lines, signal lines) 27 that are orthogonal to each other (intersect) are provided. The gate wiring lines 26 extend in the X-axis direction (second direction along the main surface 21S and intersect the first direction), and the plurality of gate wiring lines 26 are spaced apart in the Y-axis direction. The source wiring lines 27 extend in the Y-axis direction (first direction), and the plurality of source wiring lines 27 are spaced apart in the X-axis direction. The TFT 24 includes a gate electrode 24A that is connected to the gate wiring line 26, a source electrode 24B that is connected to the source wiring line 27, a drain electrode 24C that is connected to the pixel electrode 25, and a semiconductor portion 24D that is connected to the source electrode 24B and the drain electrode 24C. The TFT 24 is driven based on a scanning signal supplied to the gate electrode 24A by the gate wiring line 26. This scanning signal includes a potential higher than a threshold voltage of the TFT 24. The potential corresponding to an image signal supplied to the source electrode 24B via the source wiring line 27 is supplied to the drain electrode 24C via the semiconductor portion 24D. As a result, the pixel electrode 25 is charged to the potential corresponding to the image signal. The pixel electrode 25 is disposed in an area surrounded by the gate wiring lines 26 and the source wiring lines 27.

In the liquid crystal panel 11 according to the embodiment, as illustrated in FIG. 1 and FIG. 3, the pixel electrodes 25 and the common electrode 28 are both provided on the array substrate 21, and the liquid crystal molecules contained in the liquid crystal layer 22 are horizontally aligned by the lateral electric field generated between the pixel electrodes 25 and the common electrode 28. In other words, the liquid crystal panel 11 according to the embodiment operates in the so-called In-Plane Switching (IPS) mode. In the liquid crystal panel 11 in the IPS mode, the pixel electrodes 25 and the common electrode 28 may be comb-shaped to engage with each other in plan view, but may have other planar structures. The common electrode 28 is disposed in an area slightly larger than the display area AA as illustrated in FIG. 1, and the outer peripheral end portion is located in the non-display area NAA.

The common wiring line 29 is provided in the non-display area NAA on the array substrate 21 as illustrated in FIG. 1, and one end portion is connected to the outer peripheral end portion of the above-described common electrode 28 located in the non-display area NAA. The common wiring line 29 is connected at the other end to a specific driver 12 among the four drivers 12. Here, among the four drivers 12 arranged in the X-axis direction, two drivers 12 that are located at both ends (the left end and right end in FIG. 1) in the X-axis direction are referred to as “first drivers (first signal supply units) 12α”, and two drivers 12 that are located on a central side in the X-axis direction with respect to the two first drivers 12α are referred to as “second drivers (second signal supply units) 12β”. The common wiring line 29 is connected to the first driver 12α, and is not connected to the second driver 12β. At least two common wiring lines 29 are disposed at positions on end sides of the two first drivers 12α in the X-axis direction respectively. In this embodiment, a total of at least four common wiring lines 29 are provided, for example, two common wiring lines 29 are provided on the end side in the X-axis direction with respect to each of the first drivers 12α. The two common wiring lines 29 that are provided on the end side in the X-axis direction with respect to the first driver 12α include, the common wiring line 29 that is connected, in the outer peripheral end portion of the common electrode 28, to the end position in the X-axis direction and the end position on the driver 12 side (lower side in FIG. 1) in the Y-axis direction, and the common wiring line 29 that is connected, in the outer peripheral end portion of the common electrode 28, to the end position in the X-axis direction and the end position on the side opposite to the driver 12 side (upper side in FIG. 1) in the Y-axis direction. In other words, the four common wiring lines 29 are connected to the four corner portions of the common electrode 28 in the outer peripheral end portion respectively. To each of the two first drivers 12α, the two common wiring lines 29 are connected. The first drivers 12α are capable of supplying a common potential signal to the connected common wiring lines 29. To the common electrode 28, a common potential signal transmitted by the common wiring lines 29 are supplied such that the common electrode 28 is maintained at a common potential in accordance with the common potential signal.

In the liquid crystal panel 11 according to the embodiment, the common electrode 28 is provided on the array substrate 21, and accordingly, compared to a liquid crystal panel of the vertical alignment (VA) mode in which the common electrode is provided on the opposite substrate 20, parasitic capacitance generated between the source wiring lines 27 and the common electrode 28 is large. Accordingly, for example, when a pattern that forms a checkerboard pattern with pixels that display white and pixels that display black is displayed in a predetermined area of the display area AA, display defects called crosstalk, in which a display gradation differs from its original display gradation, is likely to occur in adjacent areas in the X-axis direction with respect to the pattern. Such crosstalk is likely caused by unstable potential of the common electrode 28 due to the parasitic capacitance between the source wiring lines 27 and the common electrode 28.

Accordingly, in the liquid crystal panel 11 according to the embodiment, the four drivers 12 are arranged as follows, as illustrated in FIG. 1. Specifically, each of the first drivers 12α is disposed such that a first interval W1 between the first driver 12α and the adjacent second driver 12β in the X-axis direction is wider than a second interval W2 between the two second drivers 12β adjacent to each other in the X-axis direction. More specifically, between one (the left end in FIG. 1) of the first drivers 12α and one second driver 12β (the left side in FIG. 1) adjacent to the first driver 12α, the first interval W1 is provided. Similarly, between the other first driver 12α (the right end in FIG. 1) and the other second driver 12β (the right side in FIG. 1) adjacent to the first driver 12α, the first interval W1 is provided. On the other hand, between the two second drivers 12β, the second interval W2, which is narrower than the first interval W1, is provided. With this structure, compared to a structure in which the first driver is disposed with respect to the second driver 12B adjacent to the first driver in the X-axis direction at the same interval as the second interval W2, the first driver 12α can be disposed closer to the end in the X-axis direction in the first end portion 21A by the difference between the first interval W1 and the second interval W2. By disposing the first driver 12α to be closer to the end in the X-axis direction in the first end portion 21A, the wiring length of the common wiring line 29 routed from the first driver 12α to the common electrode 28 can be shortened. When the wiring length of the common wiring line 29 is shortened, the wiring resistance in the common wiring line 29 is reduced, enabling the common electrode 28 to be stably maintained at a common potential. Accordingly, even if parasitic capacitance is generated between the source wiring lines 27 and the common electrode 28, a potential fluctuation is less likely to occur in the common electrode 28, and thus the occurrence of crosstalk can be suppressed.

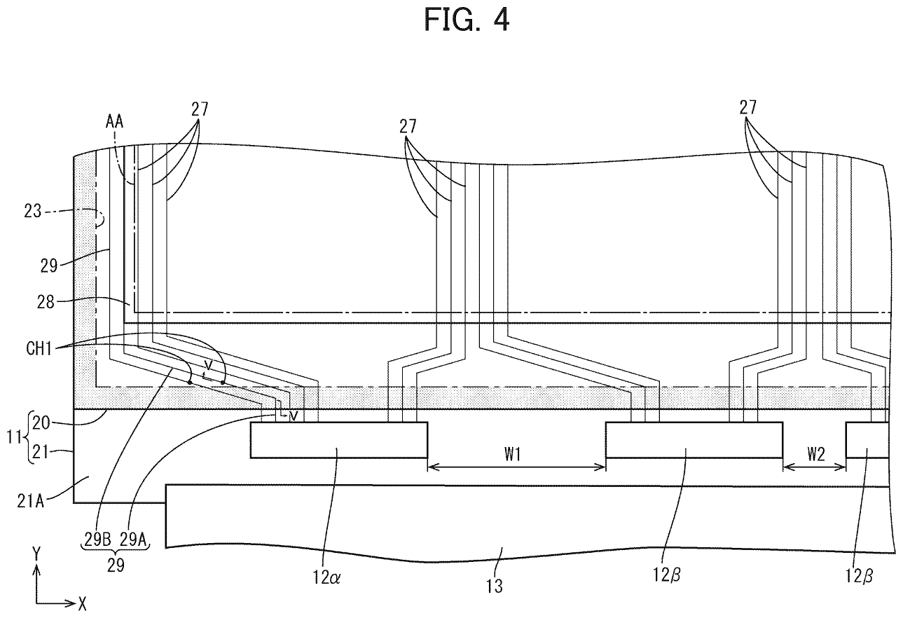

As illustrated in FIG. 4 and FIG. 5, the common wiring line 29 has a first wiring structure 29A that comprises a first metal film (first conductive film) and a second wiring structure 29B that comprises a second metal film (second conductive film). The first metal film of the first wiring structure 29A is located at the innermost position among the various films laminated on the inner surface side of the glass substrate of the array substrate 21, and is a single layer film of a single type of metal material or a laminated film or alloy that comprises different types of metal materials. The first metal film according to the embodiment is, for example, molybdenum tungsten nitride (MoWN), which has excellent weather resistance, chemical resistance, and heat resistance. The first metal film has at least higher weather resistance than the second metal film described below. The first metal film is used to form the gate wiring lines 26, the gate electrodes 24A of the TFTs 24, and other elements in display area AA.

The second metal film of the second wiring structure 29B is located on the upper layer side with respect to the above-described first metal film with a gate insulating film (first insulating film) 30 therebetween, and is a single layer film of a single type of metal material or a laminated film or alloy that comprises different types of metal materials. The second metal film according to the embodiment is, for example, a laminated film of titanium (Ti)/aluminum (Al)/Ti, and has excellent conductivity. The second metal film has higher conductivity than the first metal film, and the sheet resistance in the second metal film is lower than the sheet resistance in the first metal film. The second metal film is used, in display area AA, to form the source wiring lines 27, the source electrodes 24B and the drain electrodes 24C of the TFTs 24, and other elements.

The gate insulating film 30, which is located on the upper layer side with respect to the first metal film and on the lower layer side with respect to the second metal film, comprises an inorganic material such as silicon nitride (SiNx), silicon oxide (SiO2), or the like and is a single layer film or a laminated film. The gate insulating film 30 is, in the display area AA, provided between the gate electrodes 24A and the semiconductor portions 24D of the TFTs 24 and between the intersection portions of the gate wiring lines 26 and the source wiring lines 27, and can maintain these elements in an insulated state. The semiconductor portion 24D of TFT 24 comprises a semiconductor film provided on the upper layer side with respect to the gate insulating film 30 and on the lower layer side with respect to the second metal film. The semiconductor film comprises, for example, an oxide semiconductor material, an amorphous silicon material, or the like.

As illustrated in FIG. 4 and FIG. 5, the first wiring structure 29A is connected to the first driver 12 at one end and to the second wiring structure 29B at the other end. More specifically, one end of the first wiring structure 29A is connected to a terminal portion provided in a mounting area of the first driver 12α in the first end portion 21A of the array substrate 21. This terminal portion is connected to a bump provided to the first driver 12α via an anisotropic conductive film. The first wiring structure 29A extends from the mounting area of the first driver 12α in the Y-axis direction toward the display area AA, then bends, and extends in a diagonal direction inclined in both of the X-axis direction and the Y-axis direction. The plurality of source wiring lines 27 connected to each driver 12 are each routed to extend in a fan shape from the driver 12 side toward the display area AA side, and the fan-shaped portion extends in the oblique direction in the same manner as the first wiring structure 29A.

As illustrated in FIG. 4 and FIG. 5, the second wiring structure 29B is connected to the common electrode 28 at one end and to the first wiring structure 29A at the other end. More specifically, the second wiring structure 29B is connected to the outer peripheral end portion of the common electrode 28 at one end. The second wiring structure 29B extends from the common electrode 28 in the Y-axis direction toward the first driver 12α, then bends, and extends in a diagonal direction inclined in both of the X-axis direction and the Y-axis direction. The other end of the second wiring structure 29B is disposed to overlap the other end of the first wiring structure 29A in plan view. Each of the other ends of the first wiring structure 29A and the second wiring structure 29B is a portion that extends in a diagonal direction. In the gate insulating film 30, a first contact hole CH1 is open at a position where the first wiring structure 29A and the second wiring structure 29B overlap. The other ends of the first wiring structures 29A and the second wiring structures 29B are connected via the first contact hole CH1 in the gate insulating film 30. The second wiring structure 29B is covered by a first interlayer insulating film (second insulating film) 31 that is provided on the upper layer side of the second metal film. The first interlayer insulating film 31 comprises an inorganic material such as SiNx, SiO2, or the like in the same manner as the gate insulating film 30, and is a single layer film or a laminated film.

With this structure, when a common potential signal output from the bump of the first driver 12α is transmitted from the terminal portion to the first wiring structure 29A, the signal is transmitted via the first contact hole CH1 of the gate insulating film 30 to the second wiring structure 29B, and then supplied to the common electrode 28. The second wiring structure 29B of the common wiring line 29 comprises the second metal film having a lower sheet resistance than the first metal film, and accordingly, the wiring resistance in the common wiring line 29 can be reduced compared to a common wiring line 29 that is formed only by using the first wiring structure 29A. In addition, the first interval W1 is wider than the second interval W2 as described above, and the two first drivers 12α are disposed to be closer to the ends in the X-axis direction in the first end portion 21A. Accordingly, the wiring length of the first wiring structure 29A routed from the mounting area (terminal portion) of the first driver 12α to the first contact hole CH1 can be effectively reduced. By shortening the wiring length of the first wiring structure 29A comprising the first metal film, which has a higher sheet resistance than the second metal film, the wiring resistance in the common wiring line 29 can be effectively reduced.

The first wiring structure 29A is disposed, on the array substrate 21, in an area in which the first wiring structure 29A does not overlap at least the opposite substrate 20, as illustrated in FIG. 4. More specifically, in the first wiring structure 29A, the portion extending in the Y-axis direction from the mounting area of the first driver 12α and part of the portion extending in the diagonal direction are disposed so as not to overlap the opposite substrate 20. Accordingly, at least part of the first wiring structure 29A is exposed without being covered by the opposite substrate 20. However, the first wiring structure 29A uses the material that has low conductivity compared to the second metal film but has high weather resistance as the material for the first metal film, and accordingly, even if the first wiring structure 29A has the portion that is exposed without being covered by the opposite substrate 20, corrosion or the like is unlikely to occur over time. In contrast, the second wiring structure 29B is disposed in the area overlapping the opposite substrate 20 in the array substrate 21. In this embodiment, the entire area of the second wiring structure 29B is disposed to overlap the opposite substrate 20. In other words, the second wiring structure 29B is covered by the opposite substrate 20 and is prevented from being exposed, and accordingly, even if the material having excellent electrical conductivity but poor weather resistance is used as the material for the second metal film, corrosion or the like is unlikely to occur over time.

As illustrated in FIG. 4 and FIG. 5, the first wiring structure 29A is also disposed in the area overlapping both of the opposite substrate 20 and the sealing member 23 in the array substrate 21. In FIG. 4, the area of the sealing member 23 is shown as a shaded area. More specifically, a part of the first wiring structure 29A that extends in the diagonal direction (including the other end) is disposed so as to overlap both of the opposite substrate 20 and the sealing member 23. Accordingly, at least part of the first wiring structure 29A may be exposed to humidity or corrosive media via the sealing member 23. However, the first wiring structure 29A uses the material that has low conductivity but has high weather resistance compared to the second metal film as the material for the first metal film, and accordingly, even if the first wiring structure 29A is exposed to humidity or corrosive media via the sealing member 23 disposed in the area in which the first wiring structure 29A overlaps both of the opposite substrate 20 and the sealing member 23, corrosion or the like is unlikely to occur over time. In contrast, the second wiring structure 29B is disposed in the area in which the second wiring structure 29B does not overlap the sealing member 23 (overlaps the liquid crystal layer 22) in the array substrate 21. In this embodiment, the entire area of the second wiring structure 29B is disposed so as not to overlap the sealing member 23. Accordingly, the second wiring structure 29B is less likely to be exposed to humidity and corrosive media via the sealing member 23, and even if the material that has excellent electrical conductivity but poor weather resistance compared to the first metal film is used as the material for the second metal film, corrosion or the like is unlikely to occur over time.

Next, the following reference experiment 1 was conducted. Reference experiment 1 was conducted to obtain findings about how the crosstalk ratio changed when the number of drivers 12 attached to the liquid crystal panel 11 was varied. More specifically, in reference experiment 1, a liquid crystal panel 11 with three drivers 12 attached was used as reference example 1, and a liquid crystal panel 11 with four drivers 12 attached was used as reference example 2. The liquid crystal panels 11 in reference examples 1 and 2 had the same structure as the liquid crystal panel 11 described above, except for the arrangement of the drivers 12. In each of the liquid crystal panels 11 in reference examples 1 and 2, the drivers 12 were arranged in the first end portion 21A of the array substrate 21 such that the drivers 12 were equally spaced in the X-axis direction. The liquid crystal panel 11 in reference example 1 had a screen size of 15.1 inches. The liquid crystal panel 11 in reference example 2 had a screen size of 13.3 inches. The liquid crystal panel 11 in reference example 2 had four drivers 12, and accordingly, compared to the liquid crystal panel 11 provided with three drivers 12 in reference example 1, the drivers located at the both ends in the X-axis direction were closer to the ends in the X-axis direction, and the wiring lengths of the common wiring lines 29 were shorter.

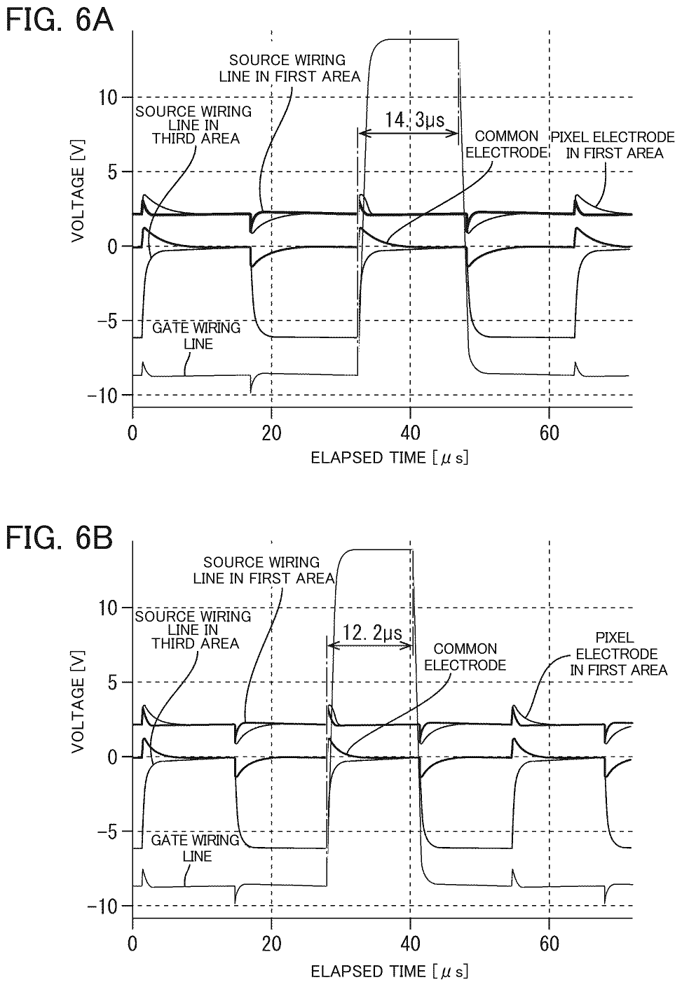

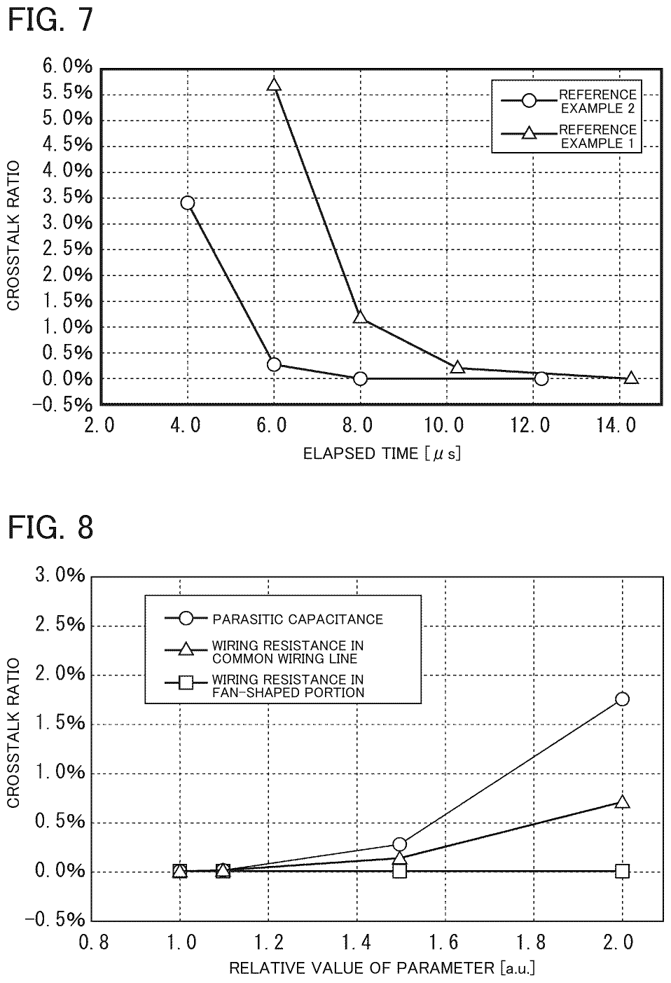

In reference experiment 1, in each of such liquid crystal panels 11 in reference examples 1 and 2, a solid pattern of intermediate tone pixels (64-level pixels) was displayed in each of a band-shaped first area, which was located at the center in the X-axis direction and extended in the Y-axis direction in the display area AA, and two band-shaped second areas, which were located at the both ends in the X-axis direction and extended in the Y-axis direction. In addition, pixels that showed white (255-level pixels) and pixels that showed black (0-level pixels) were displayed in a checkboard pattern in each of two band-shaped third areas, which were located with the first area therebetween in the X-axis direction and extended in the Y-axis direction. In this state, the luminance of predetermined pixels in the first area was measured. The luminance measured at this time is referred to as “first luminance”. In reference experiment 1, in each of the liquid crystal panels 11 in reference examples 1 and 2, a solid pattern of intermediate tone pixels was displayed across the entire display area AA, and the luminance of the above-mentioned predetermined pixels was measured in this state. The luminance measured at this time is referred to as “second luminance”. A value obtained by subtracting a second luminance from a first luminance and by dividing the obtained value by the second luminance was calculated as “crosstalk ratio”. In reference experiment 1, the solid pattern of the intermediate tone pixels (64-level pixels) was displayed in the first area and in the second areas, and the checkboard pattern of pixels showing white (255-level pixels) and pixels showing black (0-level pixels) was displayed in the third areas, and time required for the common electrode 28 to recover the potential (voltage) to a desired optimal value (common potential, Vcom value) was measured. More specifically, the potential (voltage) of the common electrode 28 surged at the timing at which the potential of the source wiring lines 27 in the third areas displaying the checkerboard pattern switched from the potential of white (255 level) to the potential of black (0 level) or at the timing at which the potential switched from the potential of black (0 level) to the potential of white (255 level). Accordingly, in reference experiment 1, the elapsed time from the timing at which the potential of the common electrode 28 surged to the timing at which the potential of the common electrode 28 reached a desired optimum value was measured. The experimental results of reference experiment 1 are shown in FIG. 6A and FIG. 6B. FIG. 6A shows the experimental results of reference example 1, and FIG. 6B shows the experimental results of reference example 2. FIG. 6A and FIG. 6B are graphs in which the vertical axis represents voltage (unit: V), and the horizontal axis represents elapsed time (unit: μs). FIG. 6A and FIG. 6B show, in addition to the potential of the common electrode 28, the potentials (voltage values) of the gate wiring lines 26, the pixel electrodes 25 and the source wiring lines 27 provided in the first area, and the source wiring lines 27 provided in the third areas. FIG. 7 is a graph in which the vertical axis represents the crosstalk ratio (unit: %) and the horizontal axis represents the elapsed time (unit: μs) until the potential of the common electrode 28 recovered to a desired optimal value. In FIG. 7, the plot of reference example 1 is indicated by “Δ” marks, and the plot of reference example 2 is indicated by “∘” marks.

The experimental results of reference experiment 1 are described below. In FIG. 6A, in reference example 1, the elapsed time from when the potential of the common electrode 28 surged at the timing the source wiring lines 27 provided in the third areas switched from the potential of white (255 level) to the potential of black (0 level), or at the timing the source wiring lines 27 switched from the potential of black (0 level) to the potential of white (255 level) to when the potential recovered to the desired optimal value was 14.3 μs. In contrast, in FIG. 6B, in reference example 2, the elapsed time until the potential of the common electrode 28 recovered to the desired optimum value was 12.2 μs. As a result, reference example 2 shows that the elapsed time in reference example 2 was shorter than that in reference example 1 by approximately 2.1 μs, and accordingly, the crosstalk was suppressed. Compared to reference example 1 in which three drivers 12 were attached, in reference example 2 in which four drivers 12 were attached, the wiring lengths of the common wiring lines 29 were short and the wiring resistance in the common wiring lines 29 was low accordingly. As a result, even when the potential of the common electrode 28 was subjected to a surge caused by potential fluctuations due to parasitic capacitance between the common electrode 28 and the source wiring lines 27, the potential readily recovered, and as a result, the reduction in the liquid crystal application voltage applied between the pixel electrodes 25 and the common electrode 28 was suppressed, and thereby the crosstalk ratio seemed to be suppressed (see FIG. 7).

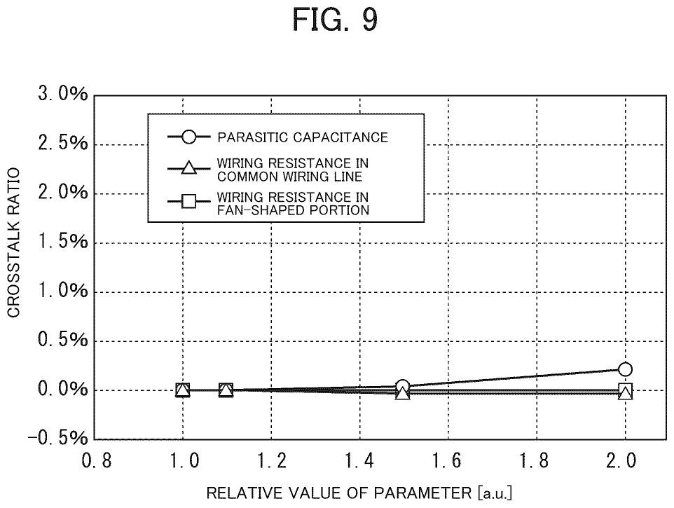

Next, the following reference experiment 2 was conducted. In reference experiment 2, the liquid crystal panels 11 in reference examples 1 and 2 in the above-described reference experiment 1 were used, and the numerical values of various parameters that were assumed to affect the crosstalk ratio were varied. Various parameters include the parasitic capacitance between the source wiring lines 27 and the common electrode 28, the wiring resistance in the common wiring lines 29, and the wiring resistance in the fan-shaped portions in the source wiring lines 27. In reference experiment 2, these various parameters were expressed as relative values based on the numerical values in reference experiment 1 as reference values (1.0). For example, when the relative value of the various parameters in reference experiment 2 was “2.0”, the values corresponding to the parameters in reference experiment 1 were doubled. Reference experiment 2 was conducted by setting the various parameters in reference examples 1 and 2 to “1.0”, “1.1”, “1.5”, and “2.0”, respectively. Specifically, regarding the parasitic capacitance between the source wiring lines 27 and the common electrode 28, when the numerical value in reference experiment 1 was, for example, “approximately 32.1 fF”, if the relative value of the above-described parasitic capacitance (parameter) was “1.1”, the numerical value of the above-described parasitic capacitance was “approximately 35.3 fF”, if the relative value of the above-described parasitic capacitance was “1.5”, the numerical value of the above-described parasitic capacitance was “approximately 48.1 fF”, and if the relative value of the above-described parasitic capacitance was “2.0”, the numerical value of the above-described parasitic capacitance was “approximately 64.1 fF”. The same applies to the wiring resistance in the common wiring lines 29 and the wiring resistance in the fan-shaped portions in the source wiring lines 27. In reference experiment 2, the various parameters in reference examples 1 and 2 were varied, and the crosstalk ratio was calculated at the point at which the experimental result (the elapsed time from the timing at which the potential of the common electrode 28 surged to the timing at which the potential of the common electrode 28 reached the desired optimum value) of reference experiment 1 had elapsed. Specifically, regarding reference example 1, the crosstalk ratio was calculated at the point at which 14.3 μs, which was the elapsed time from the timing at which the potential of the common electrode 28 surged to the point at which the potential of the common electrode 28 reached the desired optimum value, had elapsed. Regarding reference example 2, the crosstalk ratio was calculated at the point at which 12.2 μs, which was the elapsed time from the timing at which the potential of the common electrode 28 surged to the point at which the potential of the common electrode 28 reached the desired optimum value, had elapsed. It should be noted that when the relative values of the various parameters were “1.0”, the crosstalk ratio was 0%. The results of reference experiment 2 are shown in FIG. 8 and FIG. 9. The experimental results of reference experiment 2 are shown in FIG. 8 and FIG. 9. FIG. 8 shows the experimental results of reference example 1, and FIG. 9 shows the experimental results of reference example 2. FIG. 8 and FIG. 9 are graphs in which the vertical axis represents the crosstalk ratio (unit: %) and the horizontal axis represents the relative value (unit: none) of the parameter. In FIG. 8 and FIG. 9, the plot of the parasitic capacitance between the source wiring lines 27 and the common electrode 28 is indicated by “●” marks, the plot of the wiring resistance in the common wiring lines 29 is indicated by “♦” marks, and the plot of the wiring resistance in the fan-shaped portions of the source wiring lines 27 is indicated by “▪” marks.

The experimental results of reference experiment 2 are described below. FIG. 8 shows that, in reference example 1, the crosstalk ratio remained almost unchanged even when the relative values of the wiring resistance in the fan-shaped portions in the source wiring lines 27 were increased, whereas the crosstalk ratio tended to increase as the relative values of the parasitic capacitance between the source wiring lines 27 and the common electrode 28 and the wiring resistance in the common wiring lines 29 increased. In particular, as the relative values of the parasitic capacitance between the source wiring lines 27 and the common electrode 28 increased, the crosstalk ratio increased greatly. Specifically, when the relative value of the parasitic capacitance between the source wiring lines 27 and the common electrode 28 was “2.0”, the crosstalk ratio was approximately “1.75%”. In contrast, FIG. 9 shows that, in reference example 2, the crosstalk ratio remained almost unchanged even when the relative values of the wiring resistance in the common wiring lines 29 and the wiring resistance in the fan-shaped portions in the source wiring lines 27 were increased, and the crosstalk ratio increased only slightly even when the relative values of the parasitic capacitance between the source wiring lines 27 and the common electrode 28 were increased. Specifically, when the relative value of the parasitic capacitance between the source wiring lines 27 and the common electrode 28 was “2.0”, the crosstalk ratio was approximately “0.25%”. As described above, compared to reference example 1, reference example 2 seemed to generally suppress crosstalk even when various parameters were increased, and since the crosstalk was suppressed, the time required from the point at which the solid pattern of intermediate tone pixels was displayed across the entire display area AA to the point at which the crosstalk ratio reached 0% was also shortened. Compared to reference example 1 in which three drivers 12 were attached, in reference example 2 in which four drivers 12 were attached, the wiring lengths of the common wiring lines 29 were short and thereby the numerical value of the reference value of the wiring resistance in the common wiring lines 29 was low, which seems to be the main factor.

Here, in this embodiment, as illustrated in FIG. 1 and FIG. 4, the first interval W1, which is the interval between the first driver 12α and the adjacent second driver 12β in the second direction, is wider than the second interval W2, which is the interval between the two second drivers 12B adjacent to each other in the second direction. Accordingly, compared to reference example 2 in which the four drivers 12 were equally spaced, the two first drivers 12α were disposed closer to the ends in the X-axis direction in the first end portion 21A. In other words, the numerical value of the wiring resistance in the common wiring lines 29 according to the embodiment seems to be even lower than the numerical value of the reference value of the wiring resistance in the common wiring lines 29 according to reference example 2. Accordingly, from the results of reference experiments 1 and 2 described above, it seems that this embodiment can provide better results with further suppression of crosstalk than reference example 2.

As described above, the liquid crystal panel (display device) 11 according to the embodiment includes the array substrate (first substrate) 21 that has the main surface 21S that has the display area AA in which an image is to be displayed and the non-display area NAA in which the image is not to be displayed, at least one source wiring line (first wiring line) 27 that is disposed in the display area AA of the array substrate 21 and extends in the first direction, the driver (signal supply unit) 12 that is disposed in the first end portion 21A in the non-display area NAA of the array substrate 21 in the first direction and is connected at least to the at least one source wiring line 27 to supply a signal to the at least one source wiring line 27; the common electrode 28 that is disposed in the display area AA of the array substrate 21, and at least one common wiring line 29 that is disposed in the non-display area NAA of the array substrate 21 and is connected to the common electrode 28. The driver 12 includes two first drivers (first signal supply units) 12α that is disposed on the main surface 21S in the first end portion 21A and on both end sides in the second direction intersecting the first direction, and at least two second drivers (second signal supply units) 12β that are disposed between the two first drivers 12α in the second direction in the first end portion 21A and spaced apart in the second direction. The at least one common wiring line 29 comprises at least two common wiring lines 29 disposed at positions on the end sides of the two first drivers 12α in the second direction respectively, and the at least two common wiring lines 29 are connected to the two first drivers 12α respectively. The first drivers 12α are configured to supply a common potential signal to the common wiring lines 29, and each of the first drivers 12α is disposed such that the first interval W1 between the first driver 12α and the adjacent second driver 12β in the second direction is wider than the second interval W2 between the two second drivers 12 adjacent to each other in the second direction.

A common potential signal is supplied from the two first drivers 12α to at least two common wiring lines 29 that are disposed at positions on the end sides of the two first drivers 12α in the second direction respectively. The common electrode 28 is maintained at a common potential in accordance with the common potential signal supplied by the at least two common wiring lines 29. The first interval W1, which is the interval between the first driver 12α and the adjacent second driver 12β in the second direction, is wider than the second interval W2, which is the interval between the two second drivers 12β adjacent to each other in the second direction. Accordingly, compared to a case in which the first interval is the same as the second interval W2, the two first drivers 12α are disposed to be closer to the ends in the second direction in the first end portion 21A. With this structure, the wiring length of the common wiring line 29 routed from the first driver 12 to the common electrode 28 can be shortened, reducing the wiring resistance in the common wiring line 29. The reduced wiring resistance in the common wiring line 29 enables the common electrode 28 to be stably maintained at a common potential, and thereby the occurrence of crosstalk caused by potential fluctuations in the common electrode 28 can be suppressed.

Each of the common wiring lines 29 may have the first wiring structure 29A that comprises the first metal film (first conductive film) and the second wiring structure 29B that comprises the second metal film (second conductive film) that has a lower sheet resistance than the first metal film and is disposed with the gate insulating film (first insulating film) 30 disposed between the first metal film, and the first wiring structure 29A and the second wiring structure 29B may be connected via the first contact hole CH1 provided in the gate insulating film 30. The first wiring structure 29A may be connected to the first driver 12α, and the second wiring structure 29B may be connected to the common electrode 28. The common potential signal output from the first driver 12α is supplied to the common electrode 28 via the first wiring structure 29A and the second wiring structure 29B, which are connected through the first contact hole CH1 in the gate insulating film 30. The common wiring line 29 includes the second wiring structure 29B comprising the second metal film having a lower sheet resistance than the first metal film, and accordingly, the wiring resistance in the common wiring line 29 can be reduced compared to a common wiring line 29 that is formed only by using the first wiring structure 29A. As described above, the first interval W1 is wider than the second interval W2 and the two first drivers 12α are disposed to be closer to the ends in the second direction in the first end portion 21A, thereby effectively reducing the wiring length of the first wiring structure 29A connected to the first driver 12α. By shortening the wiring length of the first wiring structure 29A comprising the first metal film, which has a higher sheet resistance than the second metal film, the wiring resistance in the common wiring line 29 can be effectively reduced.

The display device may further comprise the opposite substrate (second substrate) 20 that is disposed to face the array substrate 21 with a space therebetween so as not to overlap the first end portion 21A. The first wiring structure 29A may be disposed in the area in which the first wiring structure 29A does not overlap at least the opposite substrate 20, and the second wiring structure 29B may be disposed in the area in which the second wiring structure 29B overlaps the opposite substrate 20. The first wiring structure 29A uses the material that has low conductivity compared to the second metal film but has high weather resistance as the material for the first metal film, and accordingly, even when the first wiring structure 29A is disposed in the area in which the first wiring structure 29A does not overlap at least the opposite substrate 20 and is exposed in the non-display area NAA of the array substrate 21, corrosion or the like is unlikely to occur over time. The second wiring structure 29B is disposed in the area in which the second wiring structure 29B overlaps the opposite substrate 20 and is not exposed in the non-display area NAA of the array substrate 21, and accordingly, even when the material that has excellent electrical conductivity but has poor weather resistance is used as the material for the second metal film, corrosion or the like is unlikely to occur over time.

The display device may further comprise the sealing member 23 that extends along the outer peripheral end portion of the opposite substrate 20 and is disposed between the array substrate 21 and the opposite substrate 20. The first wiring structure 29A may also be disposed in the area in which the first wiring structure 29A overlaps both of the opposite substrate 20 and the sealing member 23, and the second wiring structure 29B may be disposed in the area in which the second wiring structure 29B does not overlap the sealing member 23. The first wiring structure 29A uses a material that has low conductivity but has high weather resistance compared to the second metal film as the material for the first metal film, and accordingly, even when the first wiring structure 29A is disposed in the area in which the first wiring structure 29A overlaps both of the opposite substrate 20 and the sealing member 23 in the non-display area NAA of the array substrate 21 and is exposed to humidity or corrosive media via the sealing member 23, corrosion or the like is unlikely to occur over time. The second wiring structure 29B is disposed in the area in which the second wiring structure 29B does not overlap the sealing member 23 in the non-display area NAA of the array substrate 21 and is not likely to be exposed to humidity or corrosive media, and accordingly, even when the material that has excellent electrical conductivity but has poor weather resistance compared to the first metal film is used as the material for the second metal film, corrosion or the like is unlikely to occur over time.

The first metal film may comprise at least one of molybdenum and tungsten, and the second metal film may comprise aluminum. With the first metal film containing at least one of molybdenum and tungsten, the weather resistance of the first wiring structure 29A becomes higher than that of the second wiring structure 29B. Accordingly, even when the first wiring structure 29A is disposed in the area in which the first wiring structure 29A does not overlap at least the opposite substrate 20 and is exposed in the non-display area NAA of the array substrate 21, corrosion or the like is unlikely to occur over time in the first wiring structure 29A. With the second metal film containing aluminum, the sheet resistance of the second wiring structure 29B can be reduced to be lower than that of the first wiring structure 29A. Accordingly, the wiring resistance of the common wiring line 29 can be reduced.

### Second Embodiment

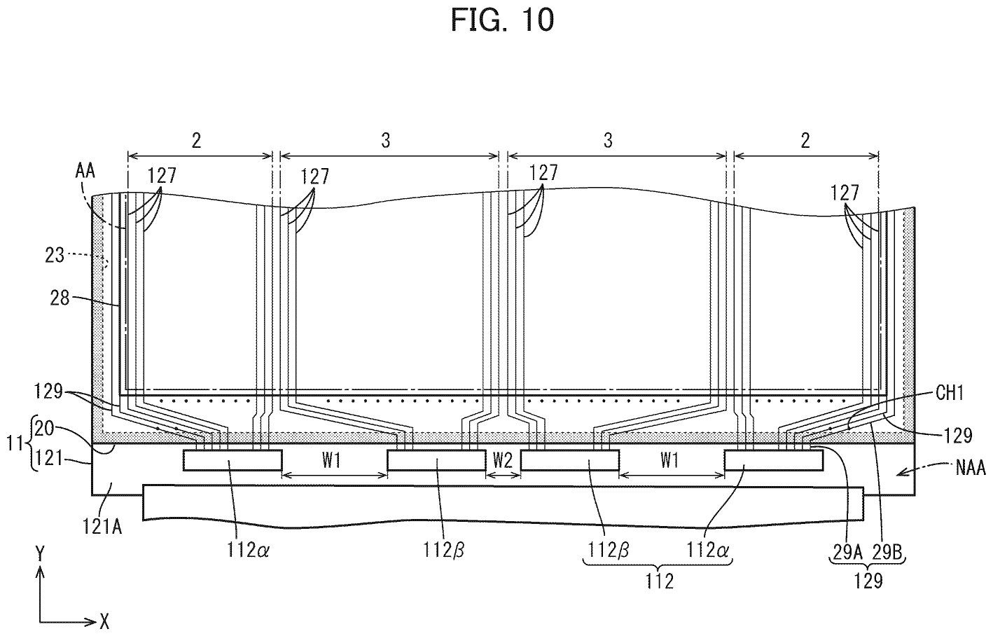

The second embodiment will be described with reference to FIG. 10. In the second embodiment, a ratio of source wiring lines 127 connected to drivers 112 is set. Descriptions of structures, operations, and effects similar to those in the above-described first embodiment will be omitted.

As illustrated in FIG. 10, drivers 112 according to the embodiment have a distribution ratio of connected source wiring lines 127 depending on the arrangement. Specifically, to a first driver 112α that is located at an end in the X-axis direction in a first end portion 121A of an array substrate 121, a smaller number of source wiring lines 127 than the number of source wiring lines 127 connected to a second driver 112β located on a center side are connected. More specifically, the ratio of the number of source wiring lines 127 connected to the first driver 112α and the number of source wiring lines 127 connected to the second driver 112β is set to “2:3”. FIG. 10 shows the ratio of the number of source wiring lines 127 connected to each of the first drivers 112α and the second drivers 112β. The number of source wiring lines 127 connected to each of the two first drivers 112α is set to ⅕ ( 2/10) of the total number of source wiring lines 127. The number of source wiring lines 127 connected to each of the two second drivers 112β is set to 3/10 of the total number of source wiring lines 127. With this structure, the first drivers 112α has a reduced load for outputting an image signal to the source wiring lines 127 compared to the second drivers 112β. Accordingly, the common potential signal can be supplied stably from the first drivers 112α to common wiring lines 129.

As described above, according to the embodiment, a plurality of source wiring lines 127 are spaced apart in the second direction and a smaller number of source wiring lines 127 than the number of source wiring lines 127 connected to the second driver 112β are connected to the first driver 112α. Since the number of source wiring lines 127 connected to the first drivers 112α is smaller than the number of source wiring lines 127 connected to the second drivers 112β, the load on the first drivers 112α is reduced. Accordingly, the common potential signal can be supplied stably from the first drivers 112α to the common wiring lines 129.

### Third Embodiment

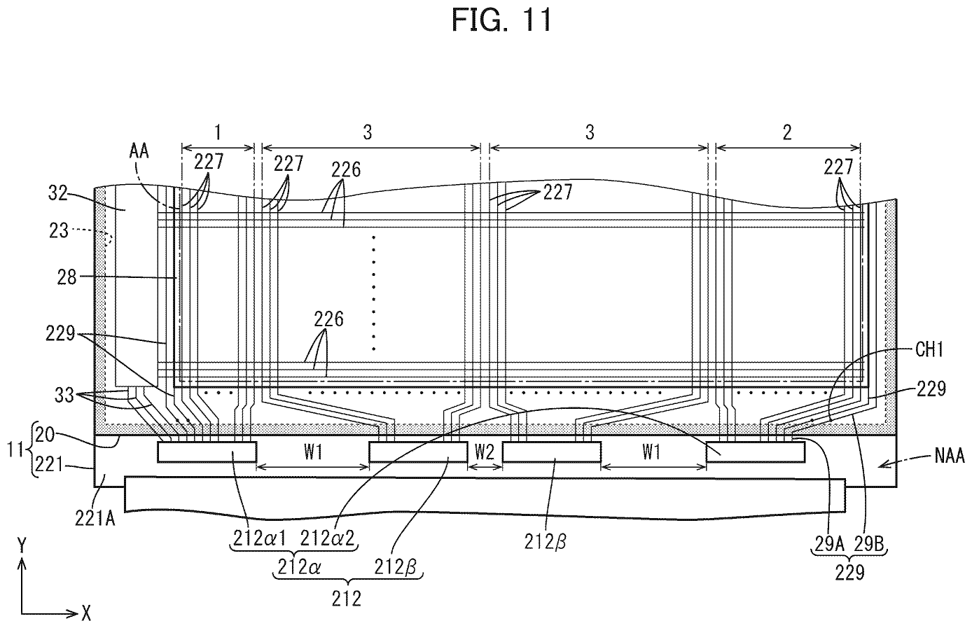

The third embodiment will be described with reference to FIG. 11. In the third embodiment, a gate drive circuit section 32 and other elements are added to the above-described second embodiment, and a ratio of source wiring lines 227 connected to drivers 212 is changed. Descriptions of structures, operations, and effects similar to those in the above-described first embodiment will be omitted.

In the non-display area NAA of an array substrate 221 according to the embodiment, as illustrated in FIG. 11, the gate drive circuit section (third signal supply unit) 32 is provided. The gate drive circuit section 32 is spaced apart with respect to the display area AA in the X-axis direction and is adjacent to one side. The gate drive circuit section 32 is disposed with portions of common wiring lines 229 between the display area AA. The gate drive circuit section 32 is provided in a long band-shaped area extending in the Y-axis direction. The gate drive circuit section 32 is connected to all gate wiring lines 226 disposed in the display area AA, and supplies a scanning signal to each gate wiring line 226. The gate drive circuit section 32 is monolithically formed on the array substrate 221.

In the non-display area NAA of the array substrate 221, a connection wiring line 33 that is connected to the gate drive circuit section 32 is provided. The connection wiring line 33 is connected at one end to the gate drive circuit section 32 and at the other end to one first driver 212α1 of two first drivers 212α. In the following description, when these two first drivers 212α are to be distinguished, a subscript “1” is added to the reference numeral of one first driver 212α, a subscript “2” is added to the reference numeral of the other first driver 212α, and no subscript is added to the reference numeral when these two first drivers 212α are not distinguished and collectively referred to. The one first driver 212α1 is disposed near an end position on the gate drive circuit section 32 side (left side in FIG. 11) in the X-axis direction in a first end portion 221A of the array substrate 221. To the connection wiring line 33, various signals (clock signals, initialization signals, gate start pulse signals, and other signals) for controlling the gate drive circuit section 32 are supplied from the one first driver 212α1. The gate drive circuit section 32 is capable of operating in accordance with various signals supplied by the connection wiring line 33 and supplying a scanning signal to a plurality of gate wiring lines 226 in a predetermined order. A plurality of connection wiring lines 33 are disposed on an end side in the X-axis direction with respect to the common wiring lines 229 and are routed parallel to the common wiring lines 229. The connection wiring lines 33 extend from the mounting area of the one first driver 212α1 in the first end portion 221A in the Y-axis direction toward the display area AA and are bent, extend in a diagonal direction toward the gate drive circuit section 32 and are bent, extend in the Y-axis direction, and are connected to an end of the gate drive circuit section 32 in the Y-axis direction. The connection wiring lines 33 are not connected to the other first driver 212α2.

In this embodiment, different numbers of source wiring lines 227 are connected to the two first drivers 212α. Specifically, to the one first driver 212α1, a smaller number of source wiring lines 227 than the number of source wiring lines 227 connected to the other first driver 212α2 are connected. More specifically, the ratio of the number of source wiring lines 227 connected to the one first driver 212α1 and the number of source wiring lines 227 connected to the other first driver 212α2 is set to “1:2”. The ratio of the number of source wiring lines 227 connected to the other first driver 212α2 and the number of source wiring lines 227 connected to the second driver 212β is set to “2:3”. FIG. 11 shows the ratio of the number of source wiring lines 227 connected to the one first driver 212α1, the other first driver 212α2, and the second driver 212β. As described above, the number of source wiring lines 227 connected to the one first driver 212α1 is set to ⅓ of the total number of source wiring lines 227, and the number of source wiring lines 227 connected to the other first driver 212α2 is set to ⅔ of the total number of source wiring lines 227. The number of source wiring lines 227 connected to each of the two second drivers 212β is set to ⅓ ( 3/9) of the total number of source wiring lines 227.

Here, the one first driver 212α1 supplies various signals for controlling the gate drive circuit section 32 to the connection wiring lines 33, and the load is higher than that on the other first driver 212α2. However, as described above, the number of source wiring lines 227 connected to the one first driver 212α1 is smaller than the number of source wiring lines 227 connected to the other first driver 212α2, and thereby the load on the first driver 212α1 can be reduced. Accordingly, the common potential signal can be supplied stably from the one first driver 212α1 to the common wiring lines 229.

As described above, the display device according to the embodiment may further include a plurality of gate wiring lines (second wiring lines) 226 disposed in the display area AA of the array substrate 221 and extending in the second direction, and the gate drive circuit section (third signal supply unit) 32 disposed adjacent to the display area AA in the second direction in the non-display area NAA of the array substrate 221. The gate drive circuit section 32 may be connected to the plurality of gate wiring lines 226, and may be configured to supply a scanning signal to the plurality of gate wiring lines 226, the one first driver 212α1 of the two first drivers 212α may be connected to the gate drive circuit section 32 and supply a signal to control the supply of the scanning signal to the gate drive circuit section 32, and to the one first driver 212α1, a smaller number of source wiring lines 227 than the number of source wiring lines 227 connected to the other first driver 212α2 may be connected. The gate drive circuit section 32 supplies a scanning signal to a plurality of gate wiring lines 226 in accordance with the signal supplied from the one first driver 212α1. Accordingly, the load on the one first driver 212α1 is higher than that on the other first driver 212α2. However, the number of source wiring lines 227 connected to the one first driver 212α1 is smaller than the number of source wiring lines 227 connected to the other first driver 212α2, and thereby the load on the one first driver 212α1 can be reduced. Accordingly, the common potential signal can be supplied stably from the one first driver 212α1 to the common wiring lines 229.

### Fourth Embodiment

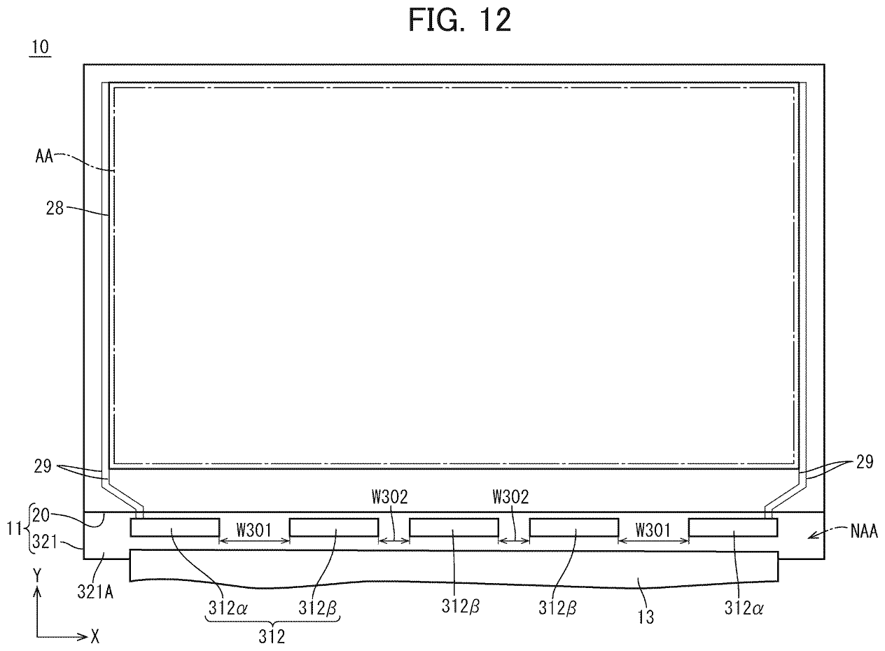

The fourth embodiment will be described with reference to FIG. 12. In the fourth embodiment, the number of drivers 312 provided is changed from that in the above-described first embodiment. Descriptions of structures, operations, and effects similar to those in the above-described first embodiment will be omitted.

To a first end portion 321A of an array substrate 321 according to the embodiment, as illustrated in FIG. 12, five drivers 312 are spaced apart in the X-axis direction. In this embodiment, among the five drivers 312 arranged in the X-axis direction, two drivers 312 located at both ends (left and right end in FIG. 12) in the X-axis direction are referred to as “first drivers 312α”, and three drivers 312 located on the center side in the X-axis direction with respect to the two first driver 312α are referred to as “second drivers 312β”. These three second drivers 312β are equally spaced apart in the X-axis direction. More specifically, among these three second drivers 312β, between the second driver 312β that is disposed at the center in the X-axis direction and the second driver 312β that is disposed on the left side in FIG. 12, a second interval W302 is provided. Among these three second drivers 312β, between the second driver 312β that is disposed at the center in the X-axis direction and the second driver 312β that is disposed on the right side in FIG. 12, the second interval W302 is provided. As described above, the second interval W302 is provided between the two directly adjacent second drivers 312β (with no other second driver 312 therebetween) in the X-axis direction, and the second interval W302 is narrower than a first interval W301 that is provided between the first driver 312α and the second driver 312β that is adjacent to the first driver 312α in the X-axis direction. This structure also provides functions and effects similar to those in the above-described first embodiment.

### OTHER EMBODIMENTS

The technology disclosed in this specification is not limited to the embodiments described above and illustrated in the drawings, but also includes, for example, the following embodiments within the scope of the technology.

1. The specific materials used for the metal films may be changed as appropriate and are not limited to the above. The first metal film may be a single layer film comprising molybdenum tungsten (MoW) or similar materials, or a laminated film comprising tungsten (W)/tantalum nitride (TaN) or similar materials. The second metal film may also be a laminated film comprising, for example, Ti/copper (Cu)/Ti or similar materials.

2. The specific formation area of the first wiring structure 29A may be changed as appropriate and is not limited to the above. For example, a part of the first wiring structure 29A may be disposed in an area in which a part of the first wiring structure 29A overlaps the opposite substrate 20 and does not overlap the sealing member 23 (overlaps the liquid crystal layer 22). In another case, for example, the first wiring structure 29A may be disposed only in an area in which the first wiring structure 29A does not overlap the opposite substrate 20.

3. The specific formation area of the second wiring structure 29B may be changed as appropriate and is not limited to the above. For example, a part of the second wiring structure 29B may be disposed in an area in which a part of the second wiring structure 29B overlaps both of the opposite substrate 20 and the sealing member 23.

4. When a third metal film is provided on the array substrates 21, 121, 221, and 321 on the upper side of the second metal film, the second wiring structure 29B may comprise the third metal film. In another case, the second wiring structure 29B may comprise the second metal film and the third metal film.

5. In the structure described in the second embodiment, the specific numerical values of the ratio of the number of source wiring lines 127 connected to the first driver 112α and the number of source wiring lines 127 connected to the second driver 112β may be changed as appropriate and are not limited to the above.

6. In the structure described in the third embodiment, the specific numerical values of the ratio of the number of source wiring lines 227 connected to the one first driver 212α1 and the number of source wiring lines 227 connected to the other first driver 212α2 may be changed as appropriate and are not limited to the above. In addition, the specific numerical values of the ratio of the number of source wiring lines 227 connected to the other first driver 212α2 and the number of source wiring lines 227 connected to the second driver 212 may be changed as appropriate and are not limited to the above.

7. As a modification of the third embodiment, two gate drive circuit sections 32 may be provided in the X-axis direction to sandwich the display area AA. In this case, to the array substrate 221, in addition to the connection wiring lines 33 connecting the one gate drive circuit section 32 and the one first driver 212α1, a connection wiring line that connects the other gate drive circuit section 32 and the other first driver 212α2 may be provided. The other first driver 212α2 supplies various signals to the other gate drive circuit section 32 via the connection wiring line. In this case, the same number of source wiring lines 227 may be connected to each of the one first driver 212α1 and the other first driver 212α2, but the number is not necessarily limited to this case.

8. In the structure described in the fourth embodiment, the interval between the second driver 312β disposed at the center in the X-axis direction and the second driver 312β disposed on the left side in FIG. 12 may differ from the distance between the second driver 312β disposed at the center in the X-axis direction and the second driver 312β disposed on the right side in FIG. 12. Even in such a case, the first interval W1 between the first driver 312α and the adjacent second driver 312β in the X-axis direction is provided to be the widest.

9. The number of each of the drivers 12, 112, 212, and 312 attached to each of the array substrates 21, 121, 221, and 321 respectively may be six or more. In such a case, the number of each of the second drivers 12β, 112β, 212β, and 312β is four or more (when the total number of each of the drivers 12, 112, 212, and 312 is denoted as “N”, it is “N−2”).

10. The specific routing paths of the common wiring lines 29, 129, 229, and 29 in the first end portions 21A, 121A, 221A, and 321A of the array substrates 21, 121, 221, and 321 respectively may be changed as appropriate and are not limited to the above. For example, the common wiring lines 29, 129, 229, and 29 may each include portions that extend in the X-axis direction.

11. The number of common wiring lines 29, 129, 229, and 29 connected to a single first driver 12α, 112α, 212α, and 312α respectively may be three or more. For example, the common wiring lines 29, 129, 229, and 29 that are connected to a central portion of the common electrode 28 other than the both end positions in the X-axis direction may be added respectively, to the side of the outer peripheral end portion of the common electrode 28 parallel to the X-axis and located on the side of drivers 12, 112, 212, and 312 in the Y-axis direction respectively.

12. The array substrates 21, 121, 221, and 321 may be provided with a switch circuit section (Source Shared Driving (SSD) circuit) that has a switch function for allocating image signals supplied from the drivers 12, 112, 212, and 312 to the source wiring lines 27, 127, 227, and 27 respectively.

13. The display mode of the liquid crystal panel 11 may be the Fringe Field Switching (FFS) mode, the Twisted Nematic (TN) mode, the Vertical Alignment (VA) mode, or the like, other than the IPS mode.

14. The liquid crystal panel 11 may also be a reflective type or a semi-transmissive type other than the transmissive type.

15. Other than the liquid crystal display device 10 that includes the liquid crystal panel 11, an organic electro luminescence (EL) display device that includes an organic EL display panel may be used.

The present disclosure contains subject matter related to that disclosed in Japanese Priority Patent Application JP 2024-115523 filed in the Japan Patent Office on Jul. 19, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a first substrate having a main surface having a display area in which an image is to be displayed and a non-display area in which the image is not to be displayed;
at least one first wiring line disposed in the display area of the first substrate and extending in a first direction;
a signal supply unit disposed in a first end portion in the non-display area of the first substrate in the first direction and connected at least to the at least one first wiring line to supply a signal to the at least one first wiring line;
a common electrode disposed in the display area of the first substrate; and
at least one common wiring line disposed in the non-display area of the first substrate and connected to the common electrode, wherein
the signal supply unit includes two first signal supply units disposed on the main surface in the first end portion and on both end sides in a second direction intersecting the first direction, and at least two second signal supply units disposed between the two first signal supply units in the second direction in the first end portion and spaced apart in the second direction,
the at least one common wiring line comprises at least two common wiring lines disposed at positions on end sides of the two first signal supply units in the second direction respectively, and the at least two common wiring lines are connected to the two first signal supply units respectively,
the first signal supply units are configured to supply a common potential signal to the common wiring lines, and
each of the first signal supply units is disposed such that a first interval between the first signal supply unit and the adjacent second signal supply unit in the second direction is wider than a second interval between the two second signal supply units adjacent to each other in the second direction.

2. The display device according to claim 1, wherein
each of the common wiring lines has a first wiring structure comprising a first conductive film and a second wiring structure comprising a second conductive film having a lower sheet resistance than the first conductive film, the second conductive film being disposed with a first insulating film disposed between the first conductive film, and the first wiring structure and the second wiring structure are connected via a first contact hole provided in the first insulating film,
the first wiring structure is connected to the first signal supply unit, and
the second wiring structure is connected to the common electrode.

3. The display device according to claim 2, further comprising:
a second substrate disposed to face the first substrate with a space therebetween so as not to overlap the first end portion, wherein
the first wiring structure is disposed in an area in which the first wiring structure does not overlap at least the second substrate, and
the second wiring structure is disposed in an area in which the second wiring structure overlaps the second substrate.

4. The display device according to claim 3, further comprising:
a sealing member extending along an outer peripheral end portion of the second substrate, the sealing member being disposed between the first substrate and the second substrate, wherein
the first wiring structure is also disposed in an area in which the first wiring structure overlaps both of the second substrate and the sealing member, and
the second wiring structure is disposed in an area in which the second wiring structure does not overlap the sealing member.

5. The display device according to claim 3, wherein
the first conductive film comprises at least one of molybdenum and tungsten, and
the second conductive film comprises aluminum.

6. The display device according to claim 1, wherein
the at least one first wiring line comprises a plurality of first wiring lines spaced apart in the second direction, and
to each of the first signal supply units, a smaller number of first wiring lines than the number of first wiring lines connected to each of the second signal supply units are connected.

7. The display device according to claim 6, further comprising:
a plurality of second wiring lines disposed in the display area of the first substrate and extending in the second direction; and
a third signal supply unit disposed adjacent to the display area in the second direction in the non-display area of the first substrate, wherein
the third signal supply unit is connected to the plurality of second wiring lines and is configured to supply a scanning signal to the plurality of second wiring lines,
one of the two first signal supply units is connected to the third signal supply unit and supplies a signal to control the supply of the scanning signal to the third signal supply unit, and
to the one first signal supply unit, a smaller number of first wiring lines than the number of first wiring lines connected to the other first signal supply unit are connected.
